(19) United States
(12) Patent Application Publication
(10) Pub. No.: US 2014/0254110 A1
(43) Pub. Date: Sep. 11, 2014

(54) ELECTRONIC DEVICE WITH SENSOR ASSEMBLY

(71) Applicant: HON HAI PRECISION INDUSTRY CO., LTD., New Taipei (TW)

(72) Inventors: WEI-SHIH CHEN, New Taipei (TW); LI-CHE LU, New Taipei (TW); SHU-YUAN KUO, New Taipei (TW)

(73) Assignee: HON HAI PRECISION INDUSTRY CO., LTD., New Taipei (TW)

(21) Appl. No.: 14/190,085

(22) Filed: Feb. 25, 2014

(30) Foreign Application Priority Data
Mar. 11, 2013 (TW) 102108391

(51) Int. Cl. H05K 1/02; G01R 1/04

(52) U.S. Cl. CPC H05K 1/028; G01R 1/04
USPC 361/749

(57) ABSTRACT

An electronic device includes a body and a sensor assembly. The body includes a circuit board. The sensor assembly includes a converting board and a sensor attached to the converting board. The converting board is electrically connected to the circuit board. The sensor is located on one side of the circuit board and has a sensing direction that is substantially parallel to the circuit board.

### FIELD

The present disclosure relates to electronic devices, and more particularly to an electronic device with a sensor assembly.

### BACKGROUND

Sensors are used electronic devices such as mobile phones and notebook computers. The sensor is usually printed on a surface of a printed circuit board. Thus, the sensor may sense objects on a top side of the printed circuit board; but cannot sense objects on lateral sides of the printed circuit board. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device.

FIG. 2 is an enlarged view of a circled portion II of FIG. 1.

FIG. 3 is an enlarged view of a circled portion III of FIG. 1.

FIG. 4 is an assembled view of the electronic device of FIG. 1.

FIG. 5 is an enlarged view of a circled portion V of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

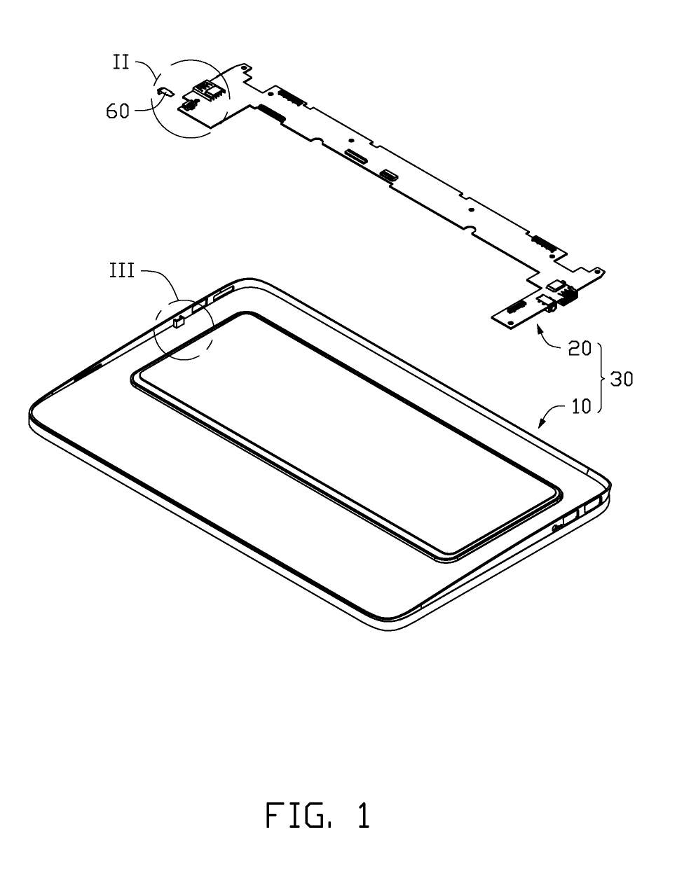

FIG. 1 illustrates an embodiment of an electronic device. The electronic device includes a body 30 and a sensor assembly 60. The electronic device may be a notebook computer, for example.

The body 30 includes a base 10 and a circuit board 20 installed on the base 10. A connector 21 is located on the circuit board 20. The circuit board 20 defines a cutout 23. The base 10 includes a bottom plate 11 and a side plate 13. The side plate 13 extends substantially perpendicularly around a periphery of the bottom plate 11. A resilient installation portion 15 is located on the bottom plate 11 and adjacent to the side plate 13. An installation slot 151 is defined in the installation portion 15. In one embodiment, the installation portion 15 is made of plastic. The side plate 13 defines an interface 131 for receiving a peripheral device (not shown), such as a mouse, a hard disk drive, a flash disc, or the like, and further defines a through hole 133 communicating with the installation slot 151.

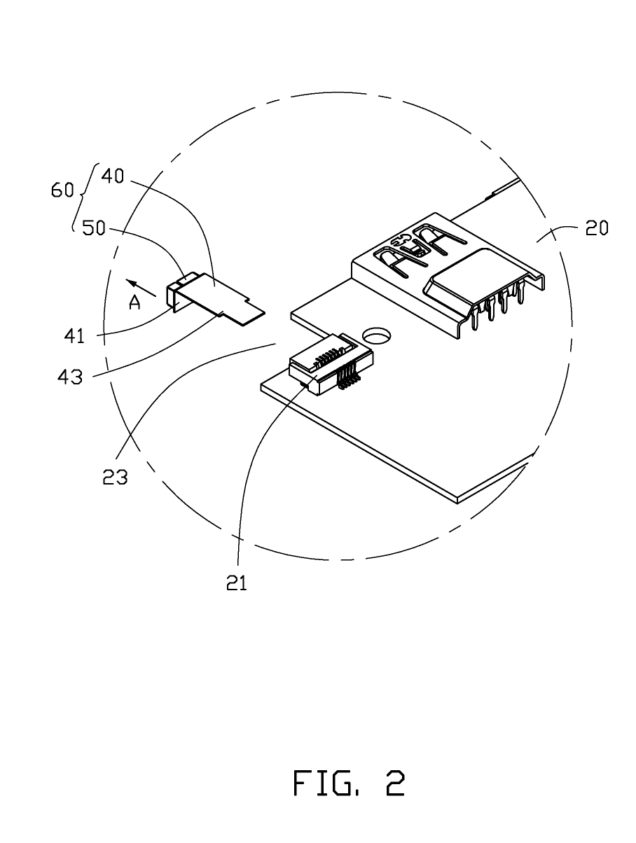

The sensor assembly 60 includes a converting board 40 and a sensor 50 attached to the converting board 40. The converting board 40 is flexible. The sensor 50 is attached to the converting board 40 and can detect whether there is a peripheral device received in the body 30. In one embodiment, the converting board 40 is a flexible printed circuit board, and the sensor 50 is an infrared sensor. Referring to FIG. 2, the converting board 40 includes a first portion 41 and a second portion 43 extending from the first portion 41. The sensor 50 is located on the first portion 41.

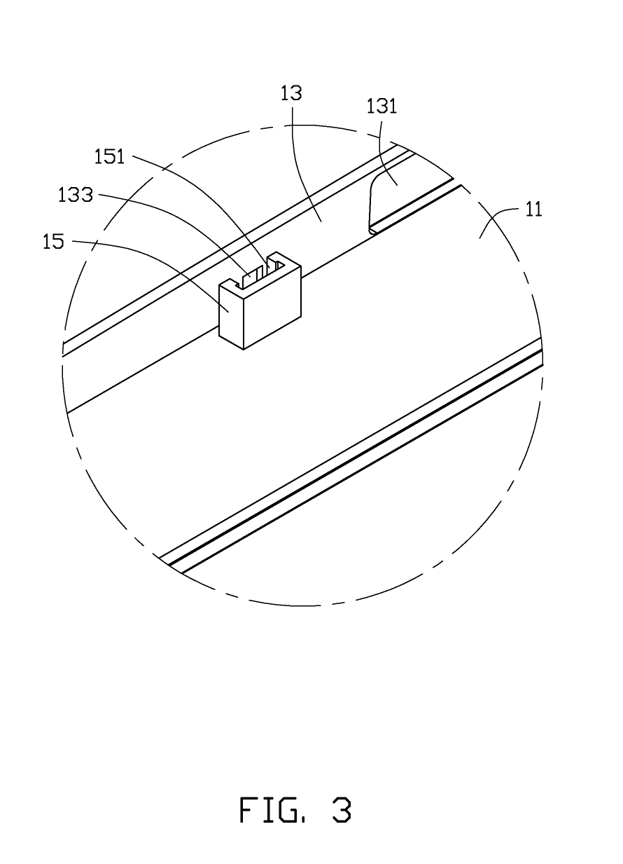

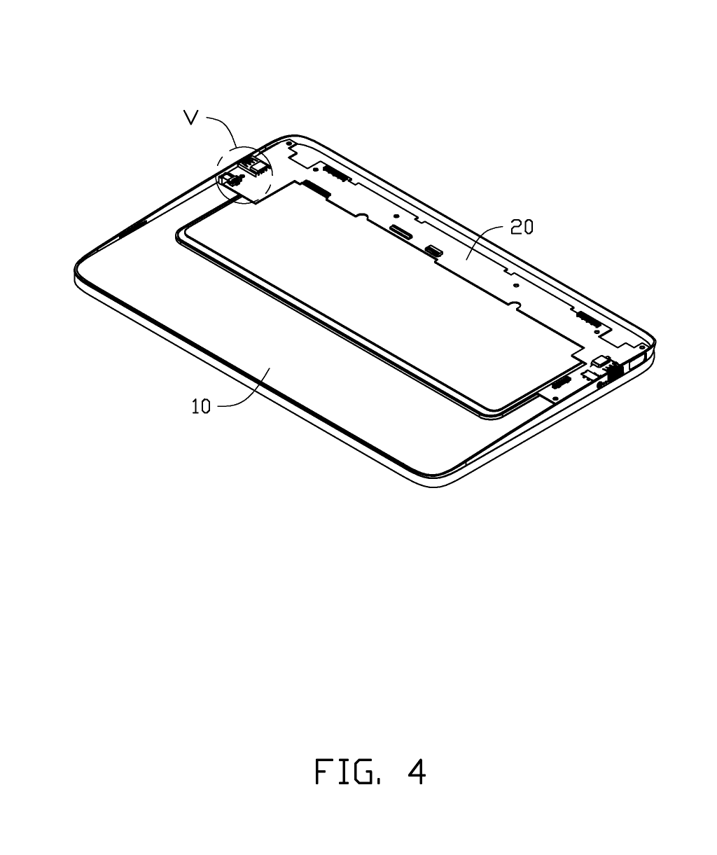

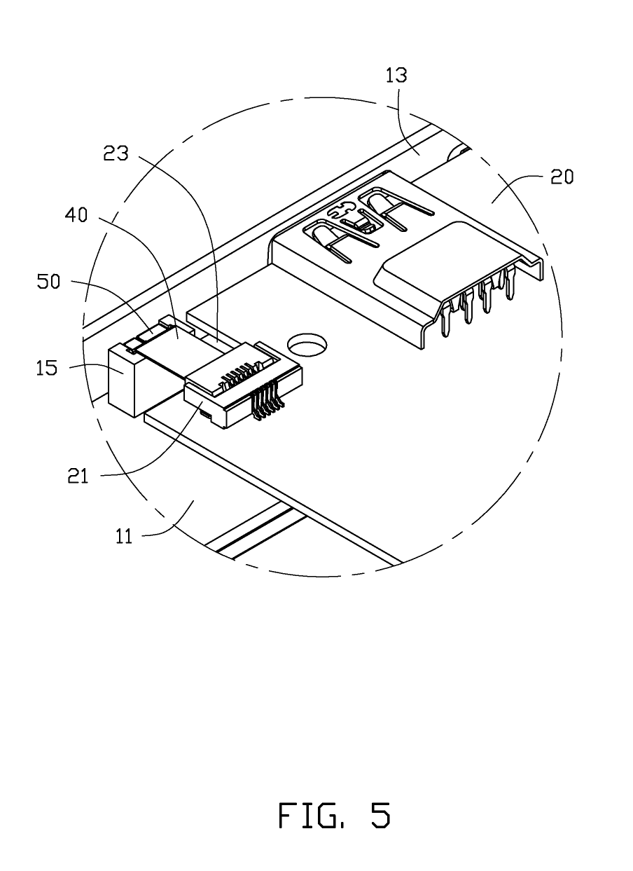

FIGS. 3-5 show that in assembly of the circuit board 20 to the bottom plate 11, the installation portion 15 is received through the cutout 23. The first portion 41 of the converting board 40 is received into the installation slot 151, such that the sensor 50 is aligned with the through hole 133 and has a sensing direction (arrow A in FIG. 2) that is substantially parallel to the circuit board 20. Thus, the sensor 50 can sense objects on a lateral side of the circuit board 20. The second portion 43 is inserted into the connector 21, such that the sensor 50 is electrically connected to the circuit board 20.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
a body comprising a circuit board; and
a sensor assembly comprising a converting board and a sensor attached to the converting board,
wherein the converting board is electrically connected to the circuit board, and the converting board is flexible to accommodate the sensor so that the sensor faces a predetermined direction.

2. The electronic device of claim 1, wherein the sensor has a sensing direction, and the sensing direction is parallel with the circuit board.

3. The electronic device of claim 1, wherein the converting board comprises a first portion and a second portion extending from the first portion, the sensor is located on the first portion, the second portion is electrically connected to the circuit board, and the first portion is perpendicular to the second portion.

4. The electronic device of claim 1, wherein a connector is located on the circuit board, and the converting board is electrically connected to the connector.

5. The electronic device of claim 2, wherein the body further comprises a base, the circuit board is attached to the base, and the sensor is engaged with the base and located on one side of the circuit board.

6. The electronic device of claim 5, wherein the base comprises a bottom plate, an installation portion is located on the bottom plate and adjacent to the circuit board, and the sensor is engaged with the installation portion.

7. The electronic device of claim 6, wherein an installation slot is defined in the installation portion, and the sensor is engaged in the installation slot.

8. The electronic device of claim 6, wherein the circuit board defines a cutout, and the installation portion is located in the cutout.

9. The electronic device of claim 6, further comprising a side plate perpendicularly extending from one side of the bottom plate, wherein the sensing direction is substantially perpendicular to the side plate.

10. The electronic device of claim 6, wherein the installation portion is made of plastic.

11. An electronic device, comprising:
a body comprising a circuit board; and
a sensor assembly comprising a converting board and a sensor attached to a first end of the converting board;
wherein a second end opposite to the first end of the converting board is electrically connected to the circuit board, and the converting board is flexible to accommodate the sensor so that the sensor faces a predetermined direction.

12. The electronic device of claim 11, wherein the sensor has a sensing direction, and the sensing direction is parallel with the circuit board.

13. The electronic device of claim 11, wherein a connector is located on the circuit board, and the converting board is electrically connected to the connector.

14. The electronic device of claim 12, wherein the body further comprises a base, the circuit board is attached to the base, and the sensor is engaged with the base.

15. The electronic device of claim 14, wherein the base comprises a bottom plate, an installation portion is located on the bottom plate and adjacent to the circuit board, and the sensor is engaged with the installation portion.

16. The electronic device of claim 15, wherein an installation slot is defined in the installation portion, and the sensor is engaged in the installation slot.

17. The electronic device of claim 15, wherein the circuit board defines a cutout, and the installation portion is located on the cutout.

18. The electronic device of claim 15, further comprising a side plate perpendicularly extending from one side of the bottom plate, wherein the sensing direction is substantially perpendicular to the side plate.

19. The electronic device of claim 15, wherein the installation portion is made of plastic.

20. The electronic device of claim 18, wherein the side plate defines a through hole in communication with the installation slot and for the sensor detecting a peripheral device.
